(19) United States
(12) Patent Application Publication
(10) Pub. No.: US 2010/0177796 A1
(43) Pub. Date: Jul. 15, 2010

(54) LASER DEVICE AND HEAT SINK WITH CORE TO MANAGE STRESS DUE TO THERMAL EXPANSION

(75) Inventor: Robert L. Miller, Tucson, AZ (US)

Correspondence Address: FOUNTAIN LAW GROUP, INC., 18201 VON KARMAN AVENUE, SUITE 960, IRVINE, CA, 92612, US

(73) Assignee: Newport Corporation, Irvine, CA (US)

(21) Appl. No.: 12/351,170

(22) Filed: Jan. 9, 2009

(51) Int. Cl. H01S 3/04; H01L 21/02

(52) U.S. Cl. 372/36; 438/46; 257/E21.002

(57) ABSTRACT

A laser module comprising a laser device attached to a heat sink that is configured to provide a relatively low thermal resistance for thermal management of the laser device, and an aggregate coefficient of thermal expansion (CTE) that is substantially matched to the CTE of the laser device for reducing stress caused by thermal cycles. The heat sink includes a shell made out of a first material, and a core situated within the shell and made out of a second material distinct from the first material of the shell. By properly selecting the first and second materials, configuring the thickness of the shell directly under the location to which the laser device will be attached with respect to the thickness of the core, the desired effective or aggregate CTE and thermal resistance of the heat sink may be achieved.

### BACKGROUND

Laser devices, such as semiconductor lasers, are used in many applications, such as medical, imaging, laser surgery, cauterizing, ranging, welding, and many other applications. Some of these are low power applications, and others are high power applications. In high power applications, semiconductor lasers generate relatively high temperatures. High temperatures on semiconductor lasers may cause damage to the devices, and typically reduce their performance characteristics including their expected operational life. Accordingly, heat sinks are typically provided with semiconductor lasers for thermal management purposes. This is better explained with reference to the following example.

FIG. 1 illustrates a side view of an exemplary conventional laser module 100. The laser module 100 consists of a laser device 102, such as a gallium-arsenide (GaAs) semiconductor laser device, and a heat sink 104 typically made of a relatively high thermal conductivity material, such as copper (Cu). The GaAs laser device 102 is attached to the Cu heat sink 104 via a bonding material 106, such as solder. The Cu material, which has a relatively high thermal conductivity of approximately 380 Watts per meter Kelvin (W/mK), serves as an adequate thermal management tool for the semiconductor laser device 102. However, as discussed below, there are also adverse issues associated with the use of the Cu heat sink 104.

In relatively high power applications, such as continuous wave (CW) or pulsed applications, the laser module 100 may be subjected to relatively high temperatures. Additionally, the laser module 100 may also be subjected to frequent thermal cycles, between room temperature and the high operating temperatures of the device. Because of the substantial difference in the coefficients of thermal expansion (CTE) of GaAs (e.g., approximately 6.5 parts per million per degree Kelvin (ppm/C.)) and Cu (e.g., approximately 17 ppm/C.), the thermal cycle that the laser module 100 undergoes creates substantial stress on the GaAs laser device 102. Such stress may cause cracks in the laser device 102, which may, in turn, cause the device to fail.

To alleviate this problem, the bonding material 106 is generally made out of a soft solder, such as Indium-based solders. Soft solders are typically used as the bonding material 106 because they have a relatively low melting temperature and have the ability to creep. Their creeping ability allows the soft solder to absorb some of the stress that develops on the laser device 102 as a result of thermal cycles. However, excessive creeping may cause solder joint failure, thus a solder that is too soft may not be ideal. It has also been observed that intermetallic compounds formed during the bonding process with soft solders lead to solder fatigue and, ultimately, to premature failure. Additionally, in a pulsing operational mode of the laser device 102, it has been observed that electromechanical solder migration occurs in soft solders.

Hard solders, such as gold-tin (AuSn), may also be used as the bonding material 106. Hard solders are less susceptible to thermal fatigue than soft solders, and have high strength that result in elastic rather than plastic deformation. However, AuSn solder is not generally a good candidate for the bonding material 106 because it does not have the creeping properties of a soft solder, and thus, the hard solder does not absorb the stress on the laser device 102 that develops during thermal cycling.

### SUMMARY

An aspect of the invention relates to a laser module comprising a laser device attached to a heat sink. The heat sink is configured to provide a relatively low thermal resistance for thermal management of the laser device. The heat sink is also configured to provide a coefficient of thermal expansion (CTE) that is substantially matched to the CTE of the laser device. In particular, the heat sink comprises a shell made out of a first material and a core comprised of a second material district from the first material. As used in this application, the term core is used to describe the relative position of the second material to the first material, i.e. the core is inside the shell, and does not indicate any particular size or shape. By properly selecting the first and second materials, configuring the relative thickness of the shell and core, and positioning, arranging and/or orienting the core, the desired effective thermal resistance and CTE for the heat sink may be achieved. As an example, the shell comprises copper, and the core comprises silver-diamond, silver-carbide, cupper-graphite, graphite foam, or cubic-boron-nitride.

In one embodiment, the CTE of the shell is greater than the CTE of the laser device. Accordingly, to decrease the effective or aggregate CTE of the heat sink to substantially match the CTE of the laser device, a core with a CTE less than the CTE of the laser device is formed within the shell. In another embodiment, the CTE of the shell is less than the CTE of the laser device. Accordingly, to increase the effective or aggregate CTE of the heat sink to substantially match the CTE of the laser device, a core with a CTE greater than the CTE of the laser device is placed within the shell. With reference to both embodiments, by properly selecting the shell and core materials, changing the relative thickness of the shell and core, and position, arrangement, and/or orientation of the core with respect to the laser device, the desired effective thermal resistance for thermal management and the desired CTE for stress reduction may be achieved.

Other aspects, advantages and novel features of the present invention will become apparent from the following detailed description of the invention when considered in conjunction with the accompanying drawings.

### BRIEF DESCRIPTION OF THE DRAWINGS

FIG. 1 illustrates a side view of an exemplary conventional laser module including a heat sink for thermal management.

FIG. 2 illustrates a perspective view of an exemplary laser module in accordance with an embodiment of the invention.

FIG. 3A illustrates a side cross-sectional view of an exemplary heat sink in accordance with an embodiment of the invention.

FIG. 3B illustrates a perspective view of an exemplary heat sink in accordance with another embodiment of the invention.

FIG. 3C illustrates a perspective view of an exemplary core in accordance with an embodiment of the invention.

FIG. 4 illustrates an overhead perspective view of an exemplary laser module in accordance with another embodiment of the invention.

FIG. 5 is a flow diagram of an exemplary method of manufacturing an embodiment of the invention.

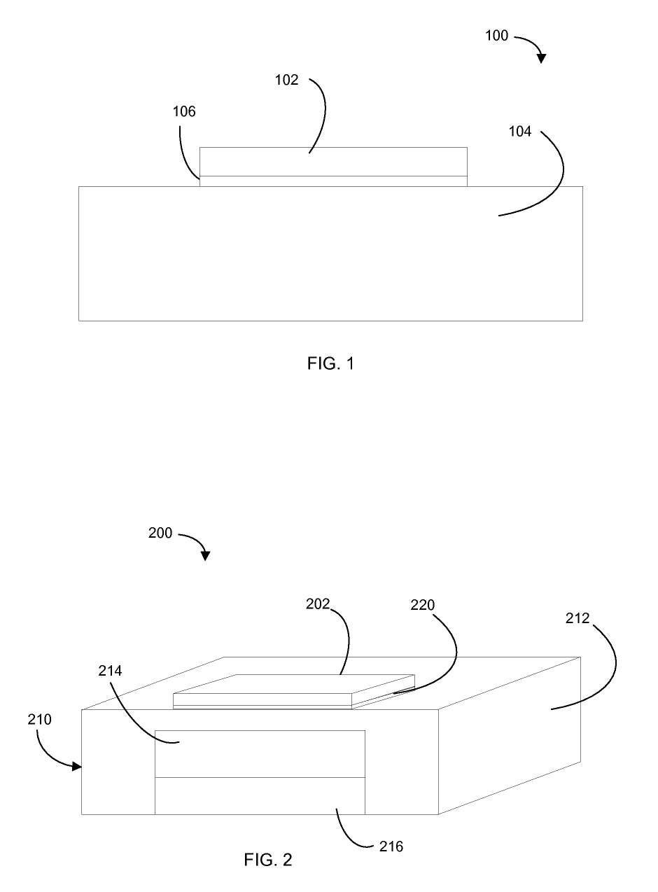

### DETAILED DESCRIPTION OF THE EXEMPLARY EMBODIMENTS

FIG. 2 illustrates a perspective view of an exemplary laser module 200 in accordance with an embodiment of the invention. The laser module 200 comprises a laser device 202 attached to a heat sink 210 by a bonding material 220. The heat sink 210, in turn, comprises a shell 212 made of a first material and a core 214 made of a second material and situated within the shell 212. The heat sink 210 further includes a plug 216 that covers the core 214 from below, and may be comprised of substantially the same material as that of the shell 212. The heat sink 210 acts as a relatively low thermal resistance device for thermal management of the laser device 202. Additionally, the heat sink 210 acts to provide an effective or aggregate coefficient of thermal expansion (CTE) that substantially matches the CTE of the laser device 202.

More specifically, the laser device 202 may be any type of laser device mountable on a heat sink. For example, the laser device 202 may be a semiconductor laser diode or other type of laser device. Some specific examples of semiconductor laser devices include galium-arsenide (GaAs) lasers, indium-phosphide (InP) lasers, and others. For the purpose of this application, the GaAs semiconductor laser serves as the particular example of laser device 202. However, it shall be understood that the invention is not limited to a GaAs semiconductor laser, and encompasses other types of lasers.

The heat sink 210 should have a substantially lower thermal resistance than the laser device 202. The thermal resistance of the heat sink may be affected by the materials forming the shell 212 and core 214, as well as other factors such as surface deformation and surface finish of the contact surfaces between the shell 212 and core 214. The intricacies of determining contact conductance is not within the scope of this application, however the net thermal resistance of the heat sink 210 should be substantially less than the thermal resistance of the laser device 202.

For providing a relatively low thermal resistance for the heat sink 210, the shell 212 may be comprised of a relatively high thermal conductive material, such as copper (Cu), a metal matrix composite such as copper graphite, or other high thermal conductive materials. For example, copper graphite has a thermal conductivity of approximately 220 to 200 W/mK in the x-y orientation. A core 214 placed within shell 212 may also aid in dispersing heat from the laser device 202. Core 214 may have a relatively high thermal conductivity relative to the laser device 202. Core 214 may be formed of such materials as silicon-diamond, silver carbide, certain graphite materials, graphite foam, cubic boron nitride (cBN), and other relatively high thermal conductive materials.

As discussed above, the heat sink 210 is configured to have an effective or aggregate CTE that is substantially matched with the CTE of the laser device 202 such that stress developed on the laser device 202 during thermal cycling and bonding is substantially reduced. The selection of the materials for the shell 212 and the core 214 is such that the heat sink 210 has a relatively low thermal resistance and has an effective or aggregate CTE that is substantially matched with the CTE of the laser device 202.

In particular, to substantially match the effective or aggregate CTE of the heat sink 210 to the CTE of the laser device 202, the material of the shell 212 and that of the core 214 should be selected based on their individual CTE and thermal conductivity. By varying the thickness of the shell 212 directly below the laser device 202 and the thickness of the core 214, the effective or aggregate CTE of the heat sink 212 may be adjusted to substantially match the CTE of the laser device 202.

As an example, the CTE of the GaAs laser device 202 may be approximately 6.5 ppm/C. The CTE of a copper graphite shell 212 may be approximately 7 (x-y) ppm/C. To lower the 7 (x-y) ppm/C. CTE of the copper graphite shell 212, a thermal pyrolytic graphite core 214 may be inserted within a pre-defined cavity of the shell 212. Since the CTE of the thermal pyrolytic graphite core 214 is relatively low, and could even be negative, i.e., expands as it cools, the effective CTE of the heat sink 210 can be configured such that it substantially matches the CTE of the GaAs laser device 202.

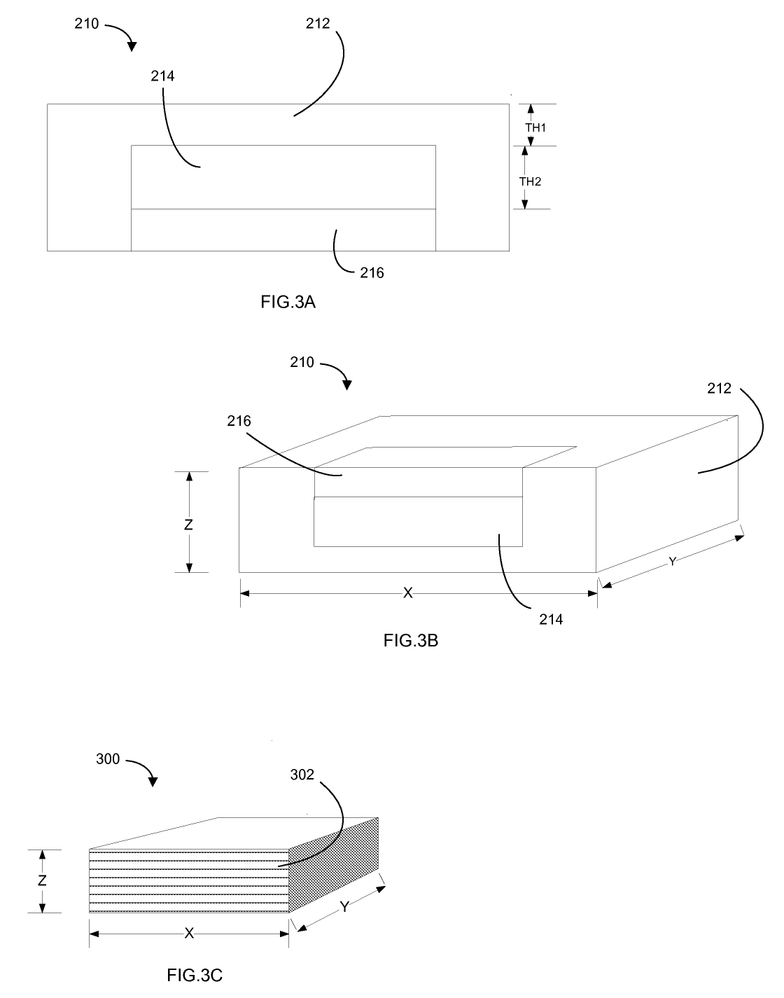

The relative thickness of shell 212 directly below the laser device 202 and the thickness of the core 214 is one factor which determines the effective or aggregate CTE of the heat sink 210. In FIG. 3A, a side view of the exemplary heat sink 210 is illustrated. In this embodiment, shell 212 surrounds core 214. Plug 216 is situated below the core 214. Plug 216 may be made of the same material as shell 212 (e.g., copper). In one embodiment, plug 216 is brazed onto core 214 and shell 212, effectively forming a cover below core 214. A finishing polish may be applied to plug 216 and shell 212 to aid thermal conductivity. In this illustration, the thickness of the shell 212 directly below the laser device is represented as TH1 and the thickness of the core 214 is represented as TH2. Thicknesses TH1 and TH2 may be altered to change the effective or aggregate CTE of the heat sink 210. For example, if the CTE of the shell 212 is greater than the CTE of the laser device 202, and the CTE of the core 214 is lower than the CTE of the laser device, then increasing the relative thickness of TH2 to TH1 should reduce the effective or aggregate CTE of the heat sink 210 so that it substantially matches the CTE of the laser device 202.

A reduction in TH1 may also achieve the same results, but the thermal resistance of heat sink 210 should be considered. TH1 should not be reduced to such a point that the heat sink 210 cannot effectively remove sufficient heat from the laser device 202.

The GaAs laser device 202, the copper graphite shell 212, and the thermal pyrolytic graphite insert 214 are merely examples of a particular configuration for the laser module 200. It shall be understood that the materials for the shell 212 and the core 214 may vary substantially, depending on the material of the laser device 202, the desired thermal resistance for the heat sink 210, and the desired matching of the effective CTE for the heat sink 210 with the CTE of the laser device 202.

In general, the selection of the material for the core 214 should be designed to “move” the effective CTE of the heat sink 210 from the CTE of the shell 212 towards the CTE of the laser device 202. In the above example, the “movement” was in the negative direction (e.g., from the 7 (x-y) ppm/C. of the copper graphite shell 212 towards the 6.5 ppm/C. of the laser device 202). It shall be understood that the movement may be in the positive direction, as in the case where the shell 212 has a CTE lower than the CTE of the laser device 202, and the insert 214 has a CTE higher than the CTE of the laser device 202. In such a case, increasing TH2 relative to TH1 will increase the effective CTE of the heat sink 210 so that it substantially matches the CTE of the laser device 202.

In another embodiment, anisotropic materials are to used form the shell 212 and core 214. Anisotropic materials exhibit physical properties that are directionally dependent. The orientation of the core 214 with respect to the shell 212 and laser device 202 may be a consideration when designing and manufacturing the heat sink 210. FIG. 3B illustrates a bottom perspective view of an exemplary heat sink 210. In this example, a pocket is formed to one side of the heat sink 210, wherein core 214 is placed and brazed to the shell 212. Then, plug 216 may be brazed onto heat sink 210 to form a seamless layer with shell 212.

As discussed above, the metal matrix composite, copper graphite, serving as a shell, has thermal and expansion properties that depend on the orientation of the material. For example, in the x-y direction (i.e., along the layer), the copper graphite material exhibits a relatively high thermal conductivity of approximately 275 to 300 W/mK, and has a CTE of approximately seven (7) ppm/C. In the z-direction (i.e., orthogonal to the x- and y-axes), the material exhibits a thermal conductivity of 220 to 230 W/mK and a CTE of 16 ppm/C. In this example, if the CTE of a GaAS laser is 6.5 ppm/C., then orienting the x,y plane of the shell 212 parallel with the bottom of the laser device 202 may substantially match the CTE of the two components in the direction of expansion more likely to cause stress fractures.

FIG. 3C illustrates an exemplary core 300 from a perspective view in accordance with another embodiment of the invention. The exemplary core 300 may be a particular example of the core 214 of the heat sink 210 discussed above. In this example, the core 300 has thermal and/or expansion properties that depend on the orientation of the core. Thermal pyrolytic graphite is an exemplary material with anisotropic properties. It shall be understood that the shell 212 discussed above can also be comprised of a material whose thermal and/or expansion properties depend on orientation, such as a metal matrix composite like copper graphite. An anisotropic core may be combined with an anisotropic shell or may be used with an isotropic shell.

The core 300 may be an example of a thermal pyrolytic graphite material. The pyrolytic graphite core 300 is formed of a plurality of layers of carbon monotube arrays 302 in a stacked relationship. In this example, the thermal pyrolytic graphite core 300 is configured as a cubic or rectangular solid having the three Cartesian axes, x-, y-, and z-. It shall be understood that the configuration of the thermal pyrolytic graphite core 300 may take forms, such as a disk, trapezoid, etc.

The properties of the thermal pyrolytic graphite core 300 depend on the orientation of the insert. For example, in a direction parallel to the layers 302, such as in the x-, y-, and x-y directions, the thermal pyrolytic graphite core 300 exhibits a significantly high thermal conductivity of approximately 1500 W/mK. Also, in these directions, the CTE of the thermal pyrolytic graphite insert 300 is very low, and can even have negative values (i.e., it shrinks with elevated temperatures). Thus, it can be strategically combined with a copper shell 212 or a copper graphite shell 212 to form a heat sink 210 that has an effective CTE substantially matched with the CTE of a GaAs semiconductor laser 202.

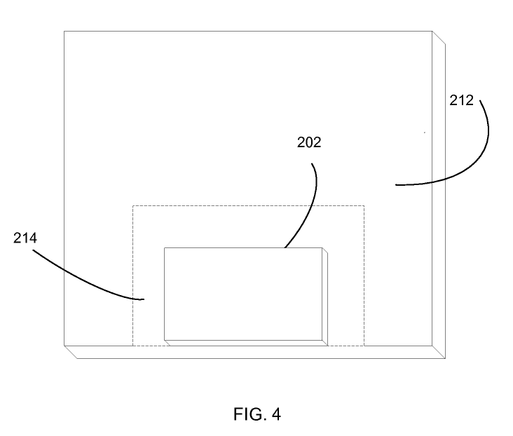

FIG. 4 is an illustration of an exemplary laser module 400 as viewed from above. In this example, a pocket is milled out of the heat sink 210 and a core 214 (not shown) is placed within the pocket. A plug 216 (not shown) is brazed onto the heat sink 210 covering the core 214. In this example the pocket is centered in the heat sink 210.

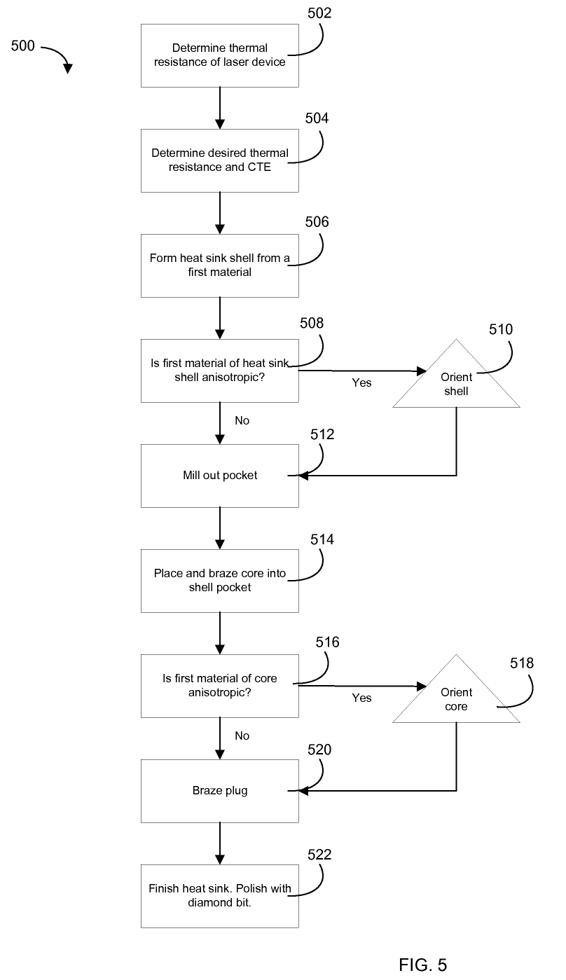

FIG. 5 illustrates an exemplary method 500 of manufacturing an exemplary embodiment of the invention is illustrated in a flow diagram. In block 502, the thermal resistance and CTE of the laser device 202 is determined. In block 504, the desired thermal resistance and CTE of the heat sink is determined. Thermal resistance of the heat sink 210 will be less than the thermal resistance of the laser device 202. Desired CTE will again be dependent on many factors but in general, the CTE of the heat sink 210 should substantially match the CTE if the laser device 202.

A shell 212 is formed of a first material in block 506. The shell 212 may be formed by casting, injection molding, stamp molding, extrusion, or other methods of metal forming. Illustrated examples of heat sink 210, have depicted a simple square or rectangular shape, however it is to be understood that heat sink 202 may be of any shape and may have heat dissipating protrusions such as pin fins to decrease thermal resistance. The first material of the shell may be chosen during block 506. A less expensive material which does not exactly match the CTE of the laser device 20 may be chosen because a core will be added in a later step which will adjust the CTE of the heat sink to desired levels. A decision is made in block 508, depending on whether the material forming the shell is anisotropic.

If the first material of the heat sink shell 212 is anisotropic, then the shell may require orientation with respect to the laser device to optimize thermal management and matching of CTE in block 510. Then a pocket is milled out of shell 212 to accommodate core 214 during block 512. In block 514, a core 214 is placed and brazed to the shell 212 within the pocket. Another decision is made in block 516 whether to orient the core 214 if the material forming the core is anisotropic. If the core 214 is anisotropic, orientation of the core may be performed in block 518. Core 214 may be attached to the heat sink by a thermally conductive adhesive such as micronized silver and ceramic epoxy. Other methods of attaching core 214 such as brazing is also within the scope of this invention.

Block 520, a plug 216 formed of substantially the same material as shell 212 or another thermally conductive material is brazed onto to heat sink 210 covering core 214. In block 522, heat sink 212 is finished to reduce surface deformation. Diamond turning, diamond compound, other polishing compound, diamond bit polishing, or other method may be used to smooth the heat sink 210, particularly the areas which contact the laser device 202, core 214, and plug 216.

While the invention has been described in connection with various embodiments, it will be understood that the invention is capable of further modifications. This application is intended to cover any variations, uses or adaptation of the invention following, in general, the principles of the invention, and including such departures from the present disclosure as come within the known and customary practice within the art to which the invention pertains.

What is claimed is:

1. A laser module, comprising:
a laser device; and
a heat sink to which the laser device is attached, wherein the heat sink comprises:
a shell comprised of a first material; and
a core situated within the shell and comprised of a second material distinct from the first material of the shell;
wherein an aggregate CTE of the heat sink is substantially matched with the CTE of the laser device.

2. The laser module of claim 1, wherein the laser device comprises a semiconductor laser.

3. The laser module of claim 1, wherein the first material of the shell comprises copper, copper graphite, or any combination thereof.

4. The laser module of claim 1, wherein the first material of the shell has thermal or expansion property dependent on orientation of the first material.

5. The laser module of claim 4, wherein the first material of the shell is oriented in a manner that substantially reduces an effective thermal resistance of the heat sink for the laser device.

6. The laser module of claim 1, wherein the second material of the core has thermal and expansion property dependent on orientation of the second material.

7. The laser module of claim 6, wherein the second material of the core is oriented in a manner that substantially reduces effective thermal resistance of the heat sink for the laser device.

8. The laser module of claim 1, wherein the second material of the core comprises thermal pyrolytic graphite, silicon carbide, diamond, silver diamond, graphite foam, cubic boron nitride or any combination thereof.

9. The laser module of claim 1, wherein the heat sink further comprises one or more cores situated within the shell.

10. The laser module of claim 1, wherein the heat sink further comprises a plug to cover at least a portion of the core.

11. The laser module of claim 10, wherein the plug is made substantially of the first material of the shell.

12. A laser module, comprising:
a laser device formed of a first material having a first CTE; and
a heat sink to which the laser device is attached, wherein the heat sink comprises:
a shell comprised of a second material having a second CTE;
a core situated within the shell, wherein the core comprises a third material having a third CTE; and
wherein the second CTE is greater than the first CTE, and wherein the third CTE is less than the first CTE.

13. The laser module of claim 12, wherein an aggregate CTE of the heat sink is substantially matched with the first CTE of the laser device.

14. The laser device of claim 12, wherein a thickness of the core with respect to the thickness of the shell directly below the laser device is configured to substantially match the aggregate CTE of the heat sink to the first CTE of the laser device.

15. The laser device of claim 12, wherein the heat sink further comprises a plug to cover at least a portion of the core.

16. The laser device of claim 15, wherein the plug is made substantially of the first material of the shell.

17. A laser module, comprising:
a laser device comprised of a first material having a first CTE; and
a heat sink to which the laser device is attached, wherein the heat sink comprises:
a shell comprised of a second material having a second CTE;
a core situated within the shell, wherein the core comprises a third material having a third CTE; and
wherein the second CTE is less than the first CTE, and wherein the third CTE is greater than the first CTE.

18. The laser module of claim 17, wherein an aggregate CTE of the heat sink is substantially matched with the first CTE of the laser device.

19. The laser device of claim 17, wherein a thickness of the core with respect to a thickness of the shell directly below the laser device is configured to substantially match the aggregate CTE of the heat sink to the first CTE of the laser device.

20. The laser device of claim 17, wherein the heat sink further comprises a plug to cover at least a portion of the core.

21. The laser module of claim 17, wherein the plug is made substantially of the first material of the shell.

22. A method of manufacturing a heat sink for a laser device, wherein the heat sink comprises a shell of a first material and a core of a second material distinct from the first material of the shell, the method comprising:
forming a pocket in the shell of heat sink;
inserting the core into the pocket;
brazing a plug onto the shell to cover the core; and
finishing the heat sink to reduce surface imperfections.

23. The method of claim 22, further comprising configuring a thickness of the core and a thickness of a portion of the shell directly below where the laser device is to attach in a manner that substantially matches an aggregate CTE of the heat sink with a CTE of the laser device.

24. The method of claim 22, wherein the heat sink is finished with a diamond bit and polished to reduce surface deformation.
